(19) United States
(12) Patent Application Publication
(10) Pub. No.: US 2025/0343212 A1
(43) Pub. Date: Nov. 6, 2025

(54) SEMICONDUCTOR PACKAGE AND MANUFACTURING METHOD THEREOF

(71) Applicant: NANYA TECHNOLOGY CORPORATION, New Taipei City (TW)

(72) Inventor: Wu-Der YANG, New Taipei City (TW)

(21) Appl. No.: 18/652,774

(22) Filed: May 1, 2024

(51) Int. Cl. H01L 25/16; H01L 21/48; H01L 23/00; H01L 23/31; H01L 23/522

(52) U.S. Cl. CPC H01L 25/16; H01L 21/4853; H01L 23/3121; H01L 23/5223; H01L 24/32; H01L 24/48; H01L 24/73; H01L 2224/32245; H01L 2224/48225; H01L 2224/48245; H01L 2224/73215; H01L 2924/19041

(57) ABSTRACT

A semiconductor package includes a substrate, a chip, a capacitor, a first molding compound and a second molding compound. The substrate has a first surface, a second surface and an opening, wherein the first surface is opposite to the second surface. The chip is located on the first surface of the substrate and in the opening of the substrate. The capacitor overlaps the chip in a vertical direction and electrically connected to the chip. A first molding compound covers the chip and the first surface of the substrate. The second molding compound covers the capacitor and the second surface of the substrate.

### BACKGROUND

### Field of Invention

The present disclosure relates to a semiconductor package and a manufacturing method of the semiconductor package.

### Description of Related Art

Generally speaking, in a semiconductor chip package, especially a chip package for dynamic random-access memory (DRAM) chips, a de-coupling capacitor (decap) is often included in order to decouple the power supply to the chip from other components and to filter noises from the power supply.

In a DRAM package, the de-coupling capacitor is usually located on the same surface of the substrate (e.g., a print circuit board) to which the chip is attached. When the initial voltage of the chip drops due to power-intensive operations, such as CAS-before-RAS (CBR) refresh, the current path from the capacitor to the chip is be too long that the discharge of the capacitor is lagged, resulting in failure of the chip.

### SUMMARY

One aspect of the present disclosure provides a semiconductor package.

According to some embodiments of the present disclosure, a semiconductor package includes a substrate, a chip, a capacitor, a first molding compound and a second molding compound. The substrate has a first surface, a second surface and an opening, wherein the first surface is opposite to the second surface. The chip is located on the first surface of the substrate and in the opening of the substrate. The capacitor overlaps the chip in a vertical direction and electrically connected to the chip. A first molding compound covers the chip and the first surface of the substrate. The second molding compound covers the capacitor and the second surface of the substrate.

In some embodiments, the capacitor is attached to the chip by a die attach film, and is located in the opening of the substrate.

In some embodiments, the capacitor is surrounded by the substrate.

In some embodiments, the second molding compound has a portion between the capacitor and the substrate.

In some embodiments, the chip has a conductive pad in the opening of the substrate, and the semiconductor package further includes a conductive line located in the second molding compound and connecting the capacitor and the conductive pad of the chip.

In some embodiments, the second surface of the substrate has a step structure adjacent to the opening, and the capacitor is located on the step structure of the substrate.

In some embodiments, the chip has a conductive pad, the substrate has a gold finger, the gold finger is located on the step structure and electrically connected to the capacitor, and the semiconductor package further includes a conductive line located in the second molding compound and connecting the conductive pad of the chip and the gold finger.

In some embodiments, the capacitor is attached to the second surface of the substrate, and the substrate has a portion between the capacitor and the chip.

In some embodiments, the chip has a conductive pad, the substrate has a gold finger, the gold finger is located on the second surface and electrically connected to the capacitor, and the semiconductor package further includes a conductive line located in the second molding compound and connecting the conductive pad of the chip and the gold finger.

In some embodiments, the semiconductor package further includes a solder ball located on the second surface of the substrate.

In some embodiments, a total height of the first molding compound, the substrate and the solder ball is in a range from 1000 micrometers to 1200 micrometers.

In some embodiments, the second molding compound has a surface facing away from the chip and the substrate, and a height of the second molding compound from the second surface of the substrate to said surface of the second molding compound is less than 200 micrometers.

One aspect of the present disclosure provides another semiconductor package.

According to some embodiments of the present disclosure, a semiconductor package includes a substrate, a chip, a capacitor, a first molding compound and a second molding compound. The substrate has a first surface, a second surface and an opening, wherein the first surface is opposite to the second surface. The chip is located on the first surface of the substrate and in the opening of the substrate. The capacitor is surrounded by the substrate or attached to the second surface of the substrate. A first molding compound covers the chip and the first surface of the substrate. The second molding compound covers the capacitor and the second surface of the substrate.

One aspect of the present disclosure provides a manufacturing method of a semiconductor package.

According to some embodiments of the present disclosure, a manufacturing method of a semiconductor package includes disposing a chip on a first surface of a substrate, wherein the substrate has an opening to expose the chip, disposing a capacitor in the opening of the substrate such that the capacitor overlaps the chip in a vertical direction, electrically connecting the capacitor to the chip, forming a first molding compound to cover the chip and the first surface of the substrate and forming a second molding compound to cover the capacitor and the second surface of the substrate.

In some embodiments, disposing the capacitor in the opening of the substrate such that the capacitor overlaps the chip in the vertical direction includes attaching the capacitor to the chip exposed through the opening of the substrate by a die attach film.

In some embodiments, the manufacturing method of the semiconductor package includes forming a step structure on the second surface of the substrate, wherein the step structure is adjacent to the opening of the substrate.

In some embodiments, disposing the capacitor in the opening of the substrate such that the capacitor overlaps the chip in the vertical direction includes attaching the capacitor to the step structure of the substrate.

In some embodiments, disposing the capacitor in the opening of the substrate such that the capacitor overlaps the chip in the vertical direction includes attaching the capacitor to the second surface of the substrate adjacent to the opening of the substrate.

In some embodiments, the manufacturing method of the semiconductor package includes forming a conductive pad on the chip, wherein the conductive pad is located in the opening of the substrate and forming a conductive line connecting the capacitor and the conductive pad of the chip.

In some embodiments, the manufacturing method of the semiconductor package includes forming a solder ball on the second surface of the substrate.

The semiconductor package described above allows the current path from the capacitor to the conductive pad of the chip to be shorter such that the capacitor can discharge more rapidly when the internal voltage of the chip drops, therefore enhancing the filtering and de-coupling efficiency of the capacitor and preventing failure of the chip. In addition, the dimensions of the semiconductor package are able to satisfy the standards of JEDEC Solid State Technology Association.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a top view of a semiconductor package according to one embodiment of the present disclosure.

FIG. 2 is a cross-sectional view of the semiconductor package taken along line 2-2 of FIG. 1.

FIGS. 3 to 7 are cross-section views at various stages of a manufacturing method of the semiconductor package of FIG. 2.

FIG. 8 is a top view of a semiconductor package according to another embodiment of the present disclosure.

FIG. 9 is a cross-sectional view of the semiconductor package taken along line 9-9 of FIG. 8.

FIG. 10 is a top view of a semiconductor package according to still another embodiment of the present disclosure.

FIG. 11 is a cross-sectional view of the semiconductor package taken along line 11-11 of FIG. 10.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

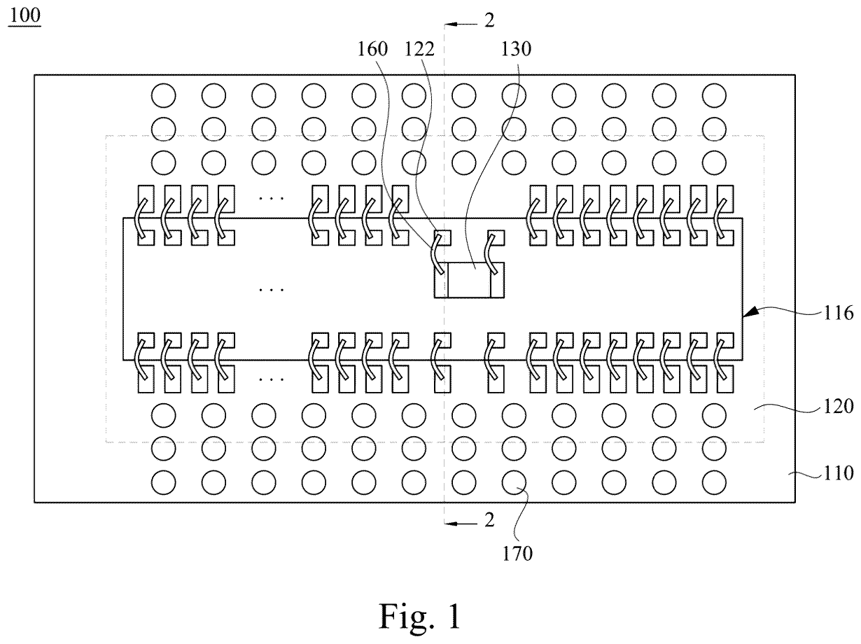

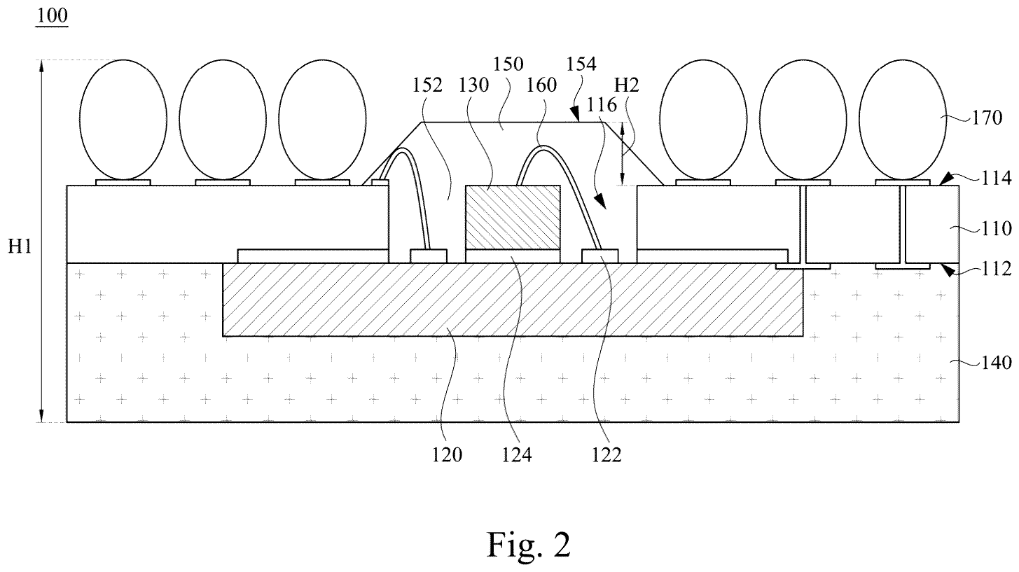

FIG. 1 is a top view of a semiconductor package 100 according to one embodiment of the present disclosure. FIG. 2 is a cross-sectional view of the semiconductor package 100 taken along line 2-2 of FIG. 1. In order to clarify and simplify FIG. 1, a second molding compound 150 shown in FIG. 2 is omitted in FIG. 1. As shown in FIG. 1 and FIG. 2, the semiconductor package 100 includes a substrate 110, a chip 120, a capacitor 130, a first molding compound 140 and the second molding compound 150. The substrate 110 has a first surface 112, a second surface 114 and an opening 116, wherein the first surface 112 is opposite to the second surface 114. In some embodiments, the substrate 110 has a thickness of about 240 micrometers. The chip 120 is located on the first surface 112 of the substrate 110, and is located in the opening 116 of the substrate 110. The capacitor 130 overlaps the chip 120 in a vertical direction, and is electrically connected to the chip 120. In some embodiments, the capacitor 130 is surrounded by the substrate 110. The first molding compound 140 covers the chip 120 and the first surface 112 of the substrate 110. In some embodiments, the first molding compound 140 and the substrate 110 have a total thickness in a range from 700 micrometers to 850 micrometers. The second molding compound 150 covers the capacitor 130 and the second surface 114 of the substrate 110.

Moreover, the chip 120 has a conductive pad 122 in the opening 116 of the substrate 110, and the semiconductor package 100 further includes a conductive line 160 located in the second molding compound 150 and connecting the capacitor 130 and the conductive pad 122. In some embodiments, the chip 120 is attached to the first surface 112 of the substrate 110 by a die attach film (DAF) 124. The chip 120 has a thickness in a range from 50 micrometers to 200 micrometers.

In some embodiments, the chip 120 is a dynamic random-access memory (DRAM) chip, and the conductive pad 122 serves as a power pad (e.g., VDD pad or GND pad) of the chip 120. In some embodiments, the capacitor 130 may be a capacitor of surface-mount device (SMD) type, and the capacitor 130 has a height less than 200 micrometers. The capacitor 130 serves as the de-coupling capacitor for the chip 120.

Specifically, the configuration of the semiconductor package 100 described above allows the current path from the capacitor 130 to the conductive pad 122 of the chip 120 to be shorter due to the position of the chip 120 and the connection of the conductive line 160. As a result, the capacitor 130 can discharge more rapidly when the internal voltage of the chip 120 drops, therefore enhancing the filtering and de-coupling efficiency of the capacitor 130 and preventing failure of the chip 120.

In addition, the second molding compound 150 has a portion 152 between the capacitor 130 and the substrate 110. That is, the portion 152 of the second molding compound 150 is in the opening 116 of the substrate 110.

In some embodiments, the semiconductor package 100 further includes a solder ball 170. The solder ball 170 is located on the second surface 114 of the substrate 110. In some embodiments, the solder ball 170 has a height in a range from 250 micrometers to 400 micrometers. The solder ball 170 serves as a terminal of the semiconductor package 100 such that the chip 120 can be connected to other related devices and systems.

Moreover, a total height H1 of the first molding compound 140, the substrate 110 and the solder ball 170 is in a range from 1000 micrometers to 1200 micrometers. Further, the second molding compound 150 has a surface 154 facing away from the chip 120 and the substrate 110, and a height H2 of the second molding compound 150 from the second surface 114 of the substrate 110 to the surface 154 of the second molding compound 150 is less than 200 micrometers. The dimensions of semiconductor package 100 are able to satisfy the standards of JEDEC Solid State Technology Association.

It is to be noted that the connection relationships, the materials, and the advantages of the elements described above will not be repeated in the following description. In the following description, the manufacturing method of the chip package 100 will be explained.

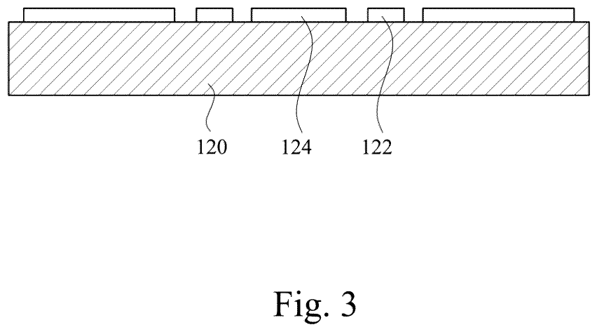

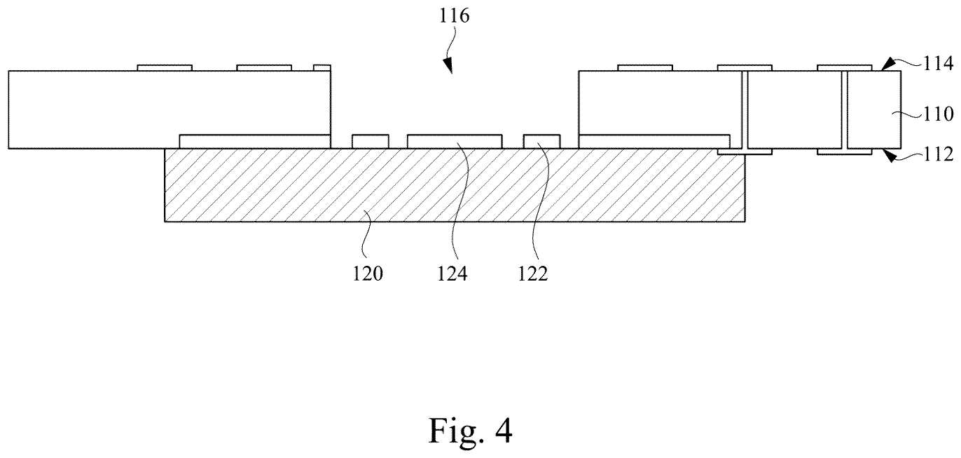

FIG. 3 to FIG. 7 are cross-section views at various stages of a manufacturing method of the semiconductor package 100 of FIG. 2. Referring to FIG. 3, the die attach film 124 is disposed on the chip 120. In some embodiments, the die attach film 124 is disposed by adhering. In addition, the conductive pad 122 is located on the chip 120. Referring to FIG. 4, thereafter, the chip 120 is attached to the first surface 112 of the substrate 110 by the die attach film 124. In this way, the chip 120 is disposed on the first surface 112 of the substrate 110, the substrate 110 has the opening 116 to expose the chip 120, and the conductive pad 122 is located in the opening 116 of the substrate 110 after the chip 120 is attached to the substrate 110.

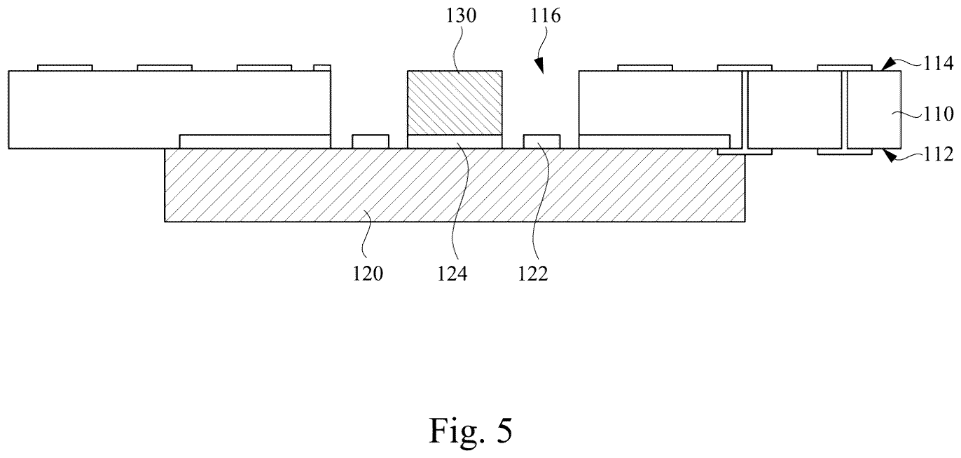

Referring to FIG. 5, thereafter, the capacitor 130 is disposed in the opening 116 of the substrate 110 such that the capacitor 130 overlaps the chip 120 in a vertical direction. In some embodiments, the capacitor 130 is attached to the chip 120 by the die attach film 124.

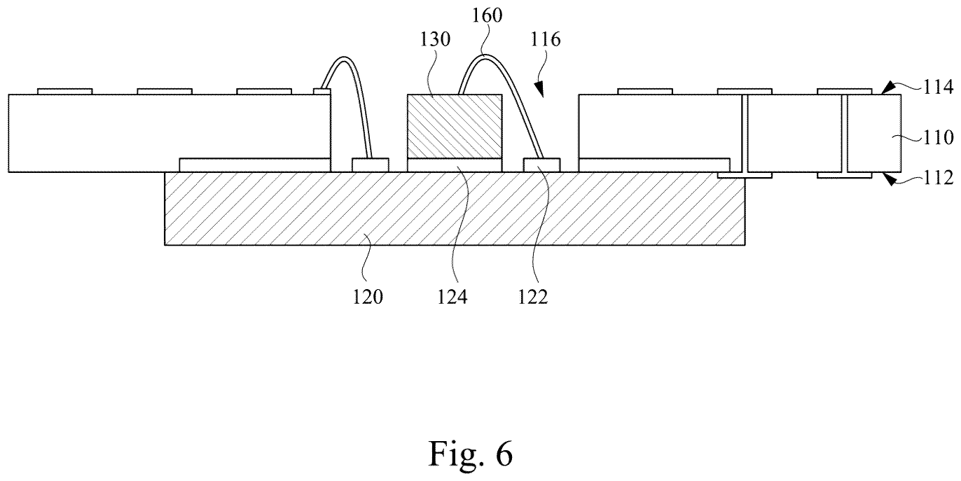

After disposing the capacitor 130 in the opening 116 of the substrate 110, referring to FIG. 6, a conductive line 160 is formed to connect the conductive pad 122 of the chip 120 and the capacitor 130 by wire bonding. In this way, the capacitor 130 is electrically connected to the chip 120.

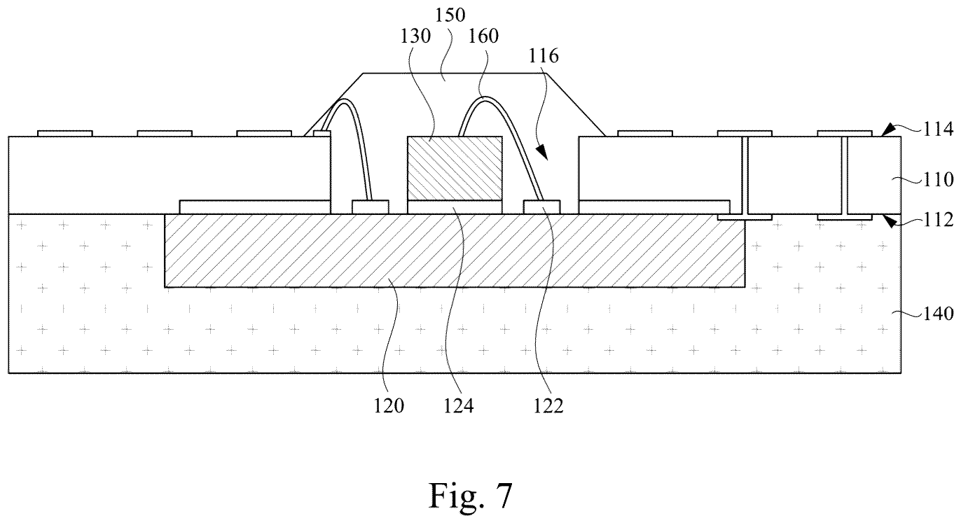

Thereafter, referring to FIG. 7, a molding process is performed, in which a first molding compound 140 is formed to cover the chip 120 and the first surface 112 of the substrate 110, and a second molding compound 150 is formed to cover the capacitor 130, the conductive line 160 and a portion of the second surface 114 of the substrate 110. In some embodiments, the first molding compound 140 and the second molding compound 150 may be formed simultaneously.

After forming the first molding compound 140 and the second molding compound 150, the solder ball 160 is formed on the second surface 114 of the substrate 110. In this way, the semiconductor package 100 in FIGS. 1 and 2 is formed.

In the following description, other types of semiconductor structures and manufacturing methods thereof will be explained.

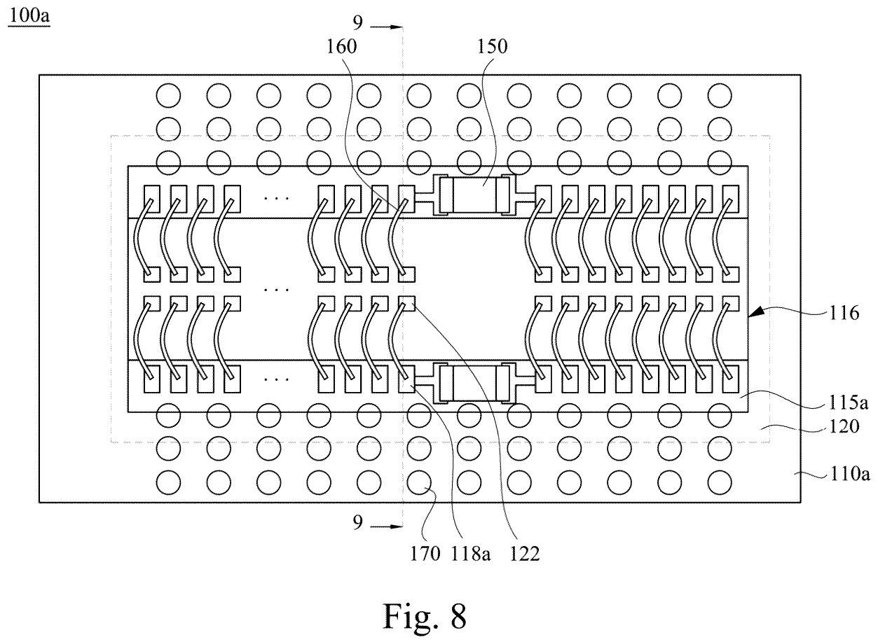

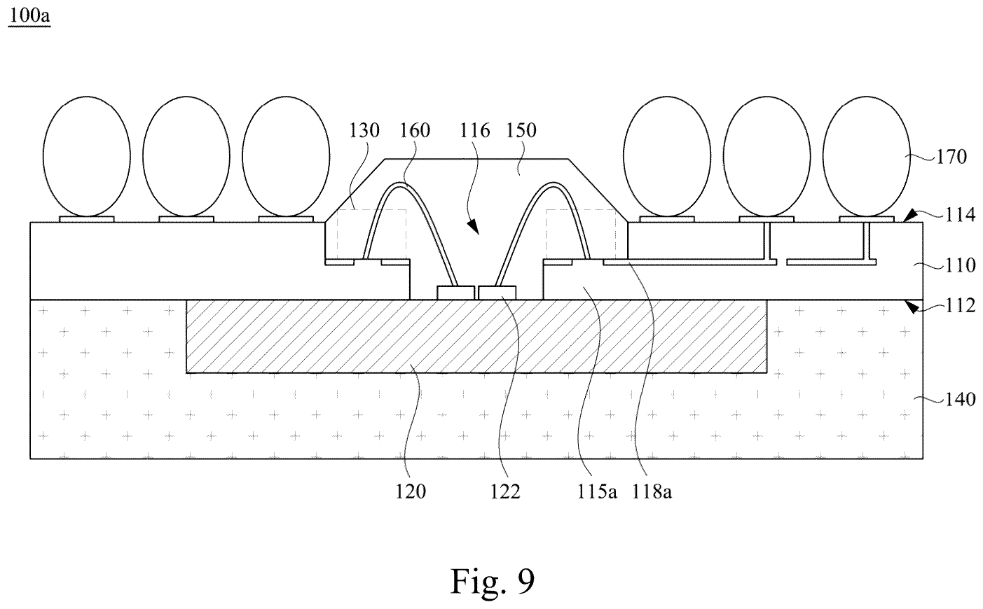

FIG. 8 is a top view of a semiconductor package 100a according to another embodiment of the present disclosure, where the second molding compound 150 is omitted. FIG. 9 is a cross-sectional view of the semiconductor package 100a taken along line 9-9 of FIG. 8. As shown in FIG. 8 and FIG. 9, the semiconductor package 100a includes a substrate 110a, the chip 120, the capacitor 130, the first molding compound 140 and the second molding compound 150. The difference between the semiconductor package 100a and the semiconductor package 100 is that the second surface 114 of the substrate 110a of the semiconductor package 100a has a step structure 115a adjacent to the opening 116, and the capacitor 130 is located on the step structure 115a of the substrate 110a. Further, the substrate 110a has a gold finger 118a, and the gold finger 118a is located on the step structure 115a and electrically connected to the capacitor 130. In addition, the conductive line 160 of the semiconductor package 100a connects the conductive pad 122 of the chip 120 and the gold finger 118a.

The difference between the manufacturing method of the semiconductor package 100a and the manufacturing method of the semiconductor package 100 is that the step structure 115a is formed on the second surface 114 of the substrate 110a and then the capacitor 130 is attached to the step structure 115a. The step structure 115a is adjacent to the opening 116 of the substrate 110a, and the capacitor 130 is located on the step structure 115a, such that the capacitor 130 overlaps the step structure 115a and the chip 120 in a vertical direction.

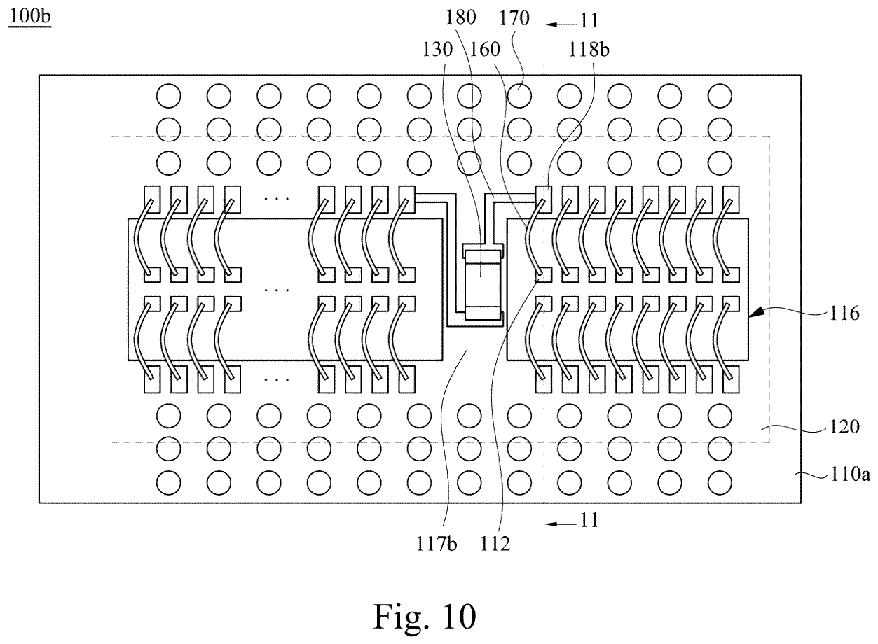

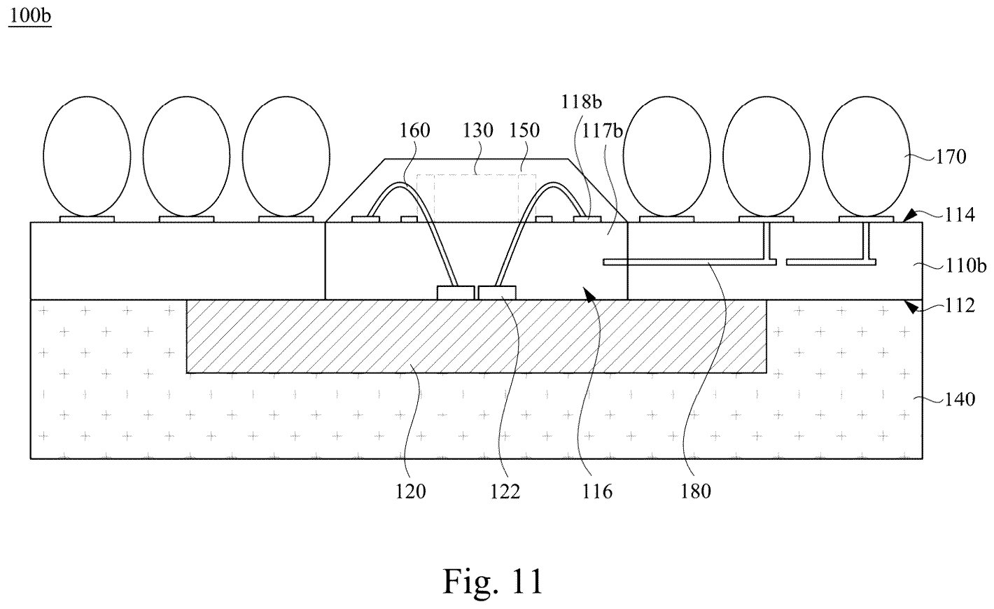

FIG. 10 is a top view of a semiconductor package 100b according to still another embodiment of the present disclosure, where the second molding compound 150 is omitted. FIG. 11 is a cross-sectional view of the semiconductor package 100b taken along line 11-11 of FIG. 10. As shown in FIG. 10 and FIG. 11, the difference between the semiconductor package 100b and the semiconductor package 100 is that the capacitor 130 is located on the second surface 114 of the substrate 110b of the semiconductor package 100b, and the substrate 110b has a portion 117b between the capacitor 130 and the chip 120, in which the capacitor 130 can be located on the portion 117b. In some embodiments, the portion 117b of the substrate 110b is a bridge-shaped portion of the substrate 110b. Furthermore, the substrate 110b has a gold finger 118b, and the gold finger 118b is located on the second surface 114 of the substrate 118b and electrically connected to the capacitor 130 by a conductive layer 180. In addition, the conductive line 160 of the semiconductor package 100b connects the conductive pad 122 of the chip 120 and the gold finger 118a.

The difference between the manufacturing method of the semiconductor package 100b and the manufacturing method of the semiconductor package 100 is that the capacitor 130 is attached to the second surface 114 of the substrate 110b adjacent to the opening 116 of the substrate 110b such that the capacitor 130 overlaps the chip 120 in a vertical direction. Specifically, the capacitor 130 is attached to the portion 117b of the substrate 110b.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a substrate having a first surface, a second surface and an opening, wherein the first surface is opposite to the second surface;
a chip located on the first surface of the substrate and in the opening of the substrate;
a capacitor overlapping the chip in a vertical direction and electrically connected to the chip;
a first molding compound covering the chip and the first surface of the substrate; and
a second molding compound covering the capacitor and the second surface of the substrate.

2. The semiconductor package of claim 1, wherein the capacitor is attached to the chip by a die attach film, and is located in the opening of the substrate.

3. The semiconductor package of claim 1, wherein the capacitor is surrounded by the substrate.

4. The semiconductor package of claim 1, wherein the second molding compound has a portion between the capacitor and the substrate.

5. The semiconductor package of claim 1, wherein the chip has a conductive pad in the opening of the substrate, and the semiconductor package further comprises:
a conductive line located in the second molding compound and connecting the capacitor and the conductive pad of the chip.

6. The semiconductor package of claim 1, wherein the second surface of the substrate has a step structure adjacent to the opening, and the capacitor is located on the step structure of the substrate.

7. The semiconductor package of claim 1, wherein the chip has a conductive pad, the substrate has a gold finger, the gold finger is located on the step structure and electrically connected to the capacitor, and the semiconductor package further comprises:
a conductive line located in the second molding compound and connecting the conductive pad of the chip and the gold finger.

8. The semiconductor package of claim 1, wherein the capacitor is attached to the second surface of the substrate, and the substrate has a portion between the capacitor and the chip.

9. The semiconductor package of claim 1, wherein the chip has a conductive pad, the substrate has a gold finger, the gold finger is located on the second surface and electrically connected to the capacitor, and the semiconductor package further comprises:
a conductive line located in the second molding compound and connecting the conductive pad of the chip and the gold finger.

10. The semiconductor package of claim 1, further comprising:
a solder ball located on the second surface of the substrate.

11. The semiconductor package of claim 10, wherein a total height of the first molding compound, the substrate and the solder ball is in a range from 1000 micrometers to 1200 micrometers.

12. The semiconductor package of claim 1, wherein the second molding compound has a surface facing away from the chip and the substrate, and a height of the second molding compound from the second surface of the substrate to said surface of the second molding compound is less than 200 micrometers.

13. A semiconductor package, comprising:
a substrate having a first surface, a second surface and an opening;
a chip located on the first surface of the substrate and in the opening of the substrate;
a capacitor electrically connected to the chip, wherein the capacitor is surrounded by the substrate or attached to the second surface of the substrate;
a first molding compound covering the chip and the first surface of the substrate; and
a second molding compound covering the capacitor and the second surface of the substrate.

14. A manufacturing method of a semiconductor package, comprising:
disposing a chip on a first surface of a substrate, wherein the substrate has an opening to expose the chip;
disposing a capacitor in the opening of the substrate such that the capacitor overlaps the chip in a vertical direction;
electrically connecting the capacitor to the chip;
forming a first molding compound to cover the chip and the first surface of the substrate; and
forming a second molding compound to cover the capacitor and the second surface of the substrate.

15. The manufacturing method of claim 14, wherein disposing the capacitor in the opening of the substrate such that the capacitor overlaps the chip in the vertical direction comprises:
attaching the capacitor to the chip exposed through the opening of the substrate by a die attach film.

16. The manufacturing method of claim 14, further comprising:
forming a step structure on the second surface of the substrate, wherein the step structure is adjacent to the opening of the substrate.

17. The manufacturing method of claim 16, wherein disposing the capacitor in the opening of the substrate such that the capacitor overlaps the chip in the vertical direction comprises:
attaching the capacitor to the step structure of the substrate.

18. The manufacturing method of claim 14, wherein disposing the capacitor in the opening of the substrate such that the capacitor overlaps the chip in the vertical direction comprises:
attaching the capacitor to the second surface of the substrate adjacent to the opening of the substrate.

19. The manufacturing method of claim 14, further comprising:
forming a conductive pad on the chip, wherein the conductive pad is located in the opening of the substrate; and
forming a conductive line connecting the capacitor and the conductive pad of the chip.

20. The manufacturing method of claim 14, further comprising:
forming a solder ball on the second surface of the substrate.
